(19) United States
(12) Patent Application Publication
(10) Pub. No.: US 2026/0026110 A1
(43) Pub. Date: Jan. 22, 2026

(54) SOLAR CELL MODULE

(71) Applicant: KANEKA CORPORATION, Osaka (JP)

(72) Inventors: Junichi NAKAMURA, Settsu-shi (JP); Toru TERASHITA, Settsu-shi (JP); Kohei KOJIMA, Settsu-shi (JP)

(73) Assignee: KANEKA CORPORATION, Osaka (JP)

(21) Appl. No.: 19/338,713

(22) Filed: Sep. 24, 2025

Related U.S. Application Data
(63) Continuation of application No. PCT/JP2024/011839, filed on Mar. 26, 2024.

(30) Foreign Application Priority Data
Mar. 29, 2023 (JP) 2023-052581

(51) Int. Cl. H10F 19/31; H10F 77/30

(52) U.S. Cl. CPC H10F 19/31; H10F 77/334

(57) ABSTRACT

A solar cell module comprising M×N solar cell submodules arranged in a two-dimensional manner in M rows and N columns (where M is an integer equal to or greater than 2 and N is an integer equal to or greater than 1). Each of the solar cell submodules includes thin-film solar cells divided in an X direction and extending in a Y direction intersecting the X direction, and connected in series and integrated; and extraction electrodes at X-direction-side ends and extending in the Y direction. In the solar cell submodules in an nth column (where n is an integer of 1-N), the solar cell submodules in the first to Mth rows are connected in parallel, and the Y-direction size of the solar cell submodule in the Mth row is less than the Y-direction size of the solar cell submodules in rows other than the Mth row.

This application claims benefit of priority to International Patent Application No. PCT/JP2024/011839, filed Mar. 26, 2024, and to Japanese Patent Application No. 2023-052581, filed Mar. 29, 2023, the entire contents of each are incorporated herein by reference.

### BACKGROUND

### Technical Field The present disclosure relates to a solar cell module.

### Background Art

Japanese Unexamined Patent Application, Publication No. 2018-157175 and Japanese Unexamined Patent Application, Publication No. 2018-157176 each disclose a solar cell module including a perovskite-based (thin-film) solar cell submodule. Solar cell submodules each include a plurality of perovskite-type (thin-film) solar battery cells which are divided (segmented) in a first direction (integration direction) and extend in a second direction intersecting the first direction on one base material, and are integrated by connecting in series.

### SUMMARY

Solar cell modules are installed in various places such as the walls of buildings and the roofs of vehicles, and solar cell modules of various sizes are required depending on the installation locations of these solar cell modules. When the thin-film solar cell submodules having various sizes are designed so as to conform to each size of the solar cell modules, it is troublesome to design the thin-film solar cell submodules.

Accordingly, thin-film solar cell submodules have been manufactured in a relatively small standard size, and the thin-film solar cell submodules of the standard size have been arranged two dimensionally so as to conform to each size of the solar cell modules. According to this method, it is not necessary to design thin-film solar cell submodules of various sizes so as to conform to each size of the solar cell modules. However, this method can only design a solar cell module having a size that is an integer multiple of the standard size of the thin-film solar cell submodules.

Therefore, the present disclosure to provide solar cell modules that are each able to be designed in various sizes.

A solar cell module according to the present disclosure is directed to a solar cell module including M×N number of solar cell submodules arranged in a two dimensional manner of M rows and N columns (where M is an integer of 2 or more and N is an integer of 1 or more). Each of the M×N number of solar cell submodules includes: a plurality of thin-film solar battery cells that are divided in a first direction and extend in a second direction intersecting the first direction on one base material, and are integrated by connecting in series; and an extraction electrode disposed at an end portion in the first direction and extending in the second direction. Among the M×N number of solar cell submodules, in a group of solar cell submodules in an n-th column (where n is an integer of 1 or more and N or less (i.e., from 1 to N)), the solar cell submodules of a first row to an M-th row are connected in parallel, and a size of the solar cell submodule in the M-th row in the second direction is smaller than a size of the solar cell submodule in each row other than the M-th row in the second direction.

According to the present disclosure, it is possible to design solar cell modules in various sizes.

### BRIEF DESCRIPTION OF THE DRAWINGS

FIG. 1 is a schematic cross-sectional view of a solar cell module according to the present embodiment;

FIG. 2 is a schematic cross-sectional view of a solar cell submodule in the solar cell module shown in FIG. 1;

FIG. 3 is a schematic plan view showing the arrangement of solar cell submodules in the solar cell module shown in FIG. 1 from the light-receiving-surface side;

FIG. 4 is a schematic plan view showing the arrangement of solar cell submodules according to a modification of FIG. 3 from the light-receiving-surface side;

FIG. 5 is a schematic plan view showing the arrangement of solar cell submodules according to a modification of FIG. 3 from the light-receiving-surface side; and

FIG. 6 is a schematic plan view showing the arrangement of solar cell submodules according to a modification of FIG. 3 from the light-receiving-surface side.

### DETAILED DESCRIPTION

Hereinafter, an example of an embodiment of the present disclosure will be described with reference to the drawings. In the drawings, the same or corresponding parts are denoted by the same reference numerals. For convenience, hatching, a reference sign of a member, and the like may be omitted, and in this case, another drawing is referenced.

### Solar Cell Module

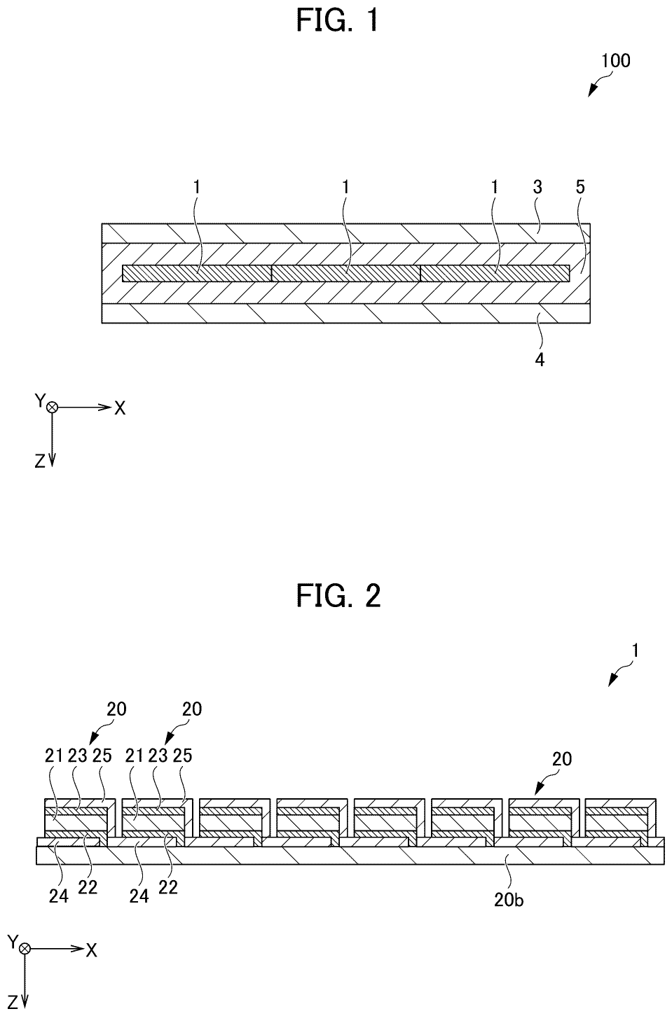

FIG. 1 is a schematic cross-sectional view of a solar cell module according to the present embodiment. The solar cell module 100 shown in FIG. 1 includes a plurality of thin-film solar cell submodules arranged in two dimensions. Details of the solar cell submodules 1 will be described later.

The solar cell submodules 1 are sandwiched between a light-receiving-side protective member 3 and a back-side protective member 4. A liquid or solid sealing material 5 is filled between the light-receiving-side protective member 3 and the back-side protective member 4, whereby the solar cell submodules 1 are sealed.

The sealing material 5 seals and protects the solar cell submodules 1, and is interposed between a light-receiving-side surface of each of the solar cell submodules 1 and the light-receiving-side protective member 3, and between a back-side surface of the solar cell submodule 1 and the back-side protective member 4. The shape of the sealing material 5 is not particularly limited, and examples thereof include a sheet shape. This is because the sheet shape makes it easy to cover the front surface and the back surface of each of the solar cell submodules 1 having a planar shape.

The material of the sealing member 5 is not particularly limited, but preferably has a light transmitting property (light transmittance). In addition, the material of the sealing material 5 preferably has adhesiveness that allows the solar cell submodule 1 and the light-receiving-side protective member 3 to be bonded together and adhesiveness that allows the solar cell submodule 1 and the back-side protective member 4 to be bonded together. Examples of such a material include light-transmitting resins such as an ethylene/vinyl acetate copolymer (EVA), ethylene/α-olefin copolymer, ethylene/vinyl acetate/triallyl isocyanurate (EVAT), polyvinyl butyral (PVB), an acrylic resin, a urethane resin, or a silicone resin.

The light-receiving-side protective member 3 covers the surfaces (light-receiving-surface) of the solar cell submodules 1 via the sealing material 5 to protect the solar cell submodules 1. The shape of the light-receiving-side protective member 3 is not particularly limited, but is preferably a plate shape or a sheet shape from the viewpoint of indirectly covering light-receiving-surface having a planar shape.

The material of the light-receiving-side protective member 3 is not particularly limited, but is preferably a material having light transmittance and resistance to ultraviolet light, similarly to the sealing material 5, and examples thereof include glass and transparent resins such as acrylic resins and polycarbonate resins. Further, the surface of the light-receiving-side protective member 3 may be processed into an uneven shape or may be covered with an anti-reflection coating layer. With such a configuration, the light-receiving-side protective member 3 is less likely to reflect the received light, and thus guides more light to the solar cell modules 1. In addition, when the material of the light-receiving-side protective member 3 is a resin, the back surface or the front surface of the light-receiving-side protective member 3 may be provided with a barrier film that prevents the passage of water vapor. With such a configuration, it is possible to protect the solar cell submodules 1 from water vapor.

The back-side protective member 4 covers the back surfaces of the solar cell submodules 1 via the sealing material 5 to protect the solar cell submodules 1. The shape of the back-side protective member 4 is not particularly limited; however, similarly to the light-receiving-side protective member 3, the back-side protective member 4 preferably has a plate shape or sheet shape from the viewpoint of indirectly covering the back surface having a planar shape.

The material of the back-side protective member 4 is not particularly limited, but it is preferable to use a material that prevents the intrusion of water or the like (high impermeability). Examples thereof include a laminate of a resin film of polyethylene terephthalate (PET), polyethylene (PE), an olefin-based resin, a fluorine-containing resin, a silicone-containing resin or the like, or glass or plate-shaped resin member having a light transmittance such as of polycarbonate or acrylic resin, and a metal foil such as an aluminum foil. When the material of the back-side protective member 4 is a resin, the front surface or the back surface of the back-side protective member 4 may be provided with a barrier film that prevents the passage of water vapor. With such a configuration, it is possible to protect the solar cell submodules 1 from water vapor.

### Solar Cell Submodule

FIG. 2 is a schematic cross-sectional view of the solar cell submodule 1 in the solar cell module 100 shown in FIG. 1. In addition, since FIG. 2 is a schematic view, the position of a base material 20b is not limited to the back side, and may be on the light-receiving side.

The solar cell submodules 1 include thin-film solar battery cells that have an inorganic semiconductor thin film, an organic semiconductor thin film, or an organic-inorganic hybrid semiconductor thin film, for example, an amorphous silicon thin film or a perovskite thin film. As shown in FIG. 2, the solar cell submodules 1 each include a plurality of thin-film solar battery cells 20 which are divided (segmented) in the X direction (integration direction: first direction) and extend in the Y direction (second direction) intersecting the X direction on one base material 20b, and are integrated by connecting in series. This makes it possible to reduce the amount of current per cell 20 while shortening the conduction distance in the X direction, and as a result, it is possible to reduce the resistance loss due to the electrodes 24 and 25, particularly electrodes 24 and 25 formed of transparent electrodes (ITO).

The base material 20b is, for example, a flat plate-shaped or sheet-shaped base material. Examples of the material of the base material 20b include polyethylene terephthalate (PET), polyethylene naphthalate (PEN), polyimide (PI), and glass.

Hereinafter, the solar cell submodule 1 including perovskite-type solar battery cells as the thin-film solar battery cells 20, will be exemplified. The solar battery cells 20 each include a perovskite layer 21 as a photoelectric conversion layer, charge transport layers 22 and 23, and electrodes 24 and 25.

The perovskite layer 21 is a photoelectric conversion layer, and absorbs light to generate photocarriers. The compound constituting the perovskite-type crystalline material is represented by the general formula R¹NH₃M¹X₃ or HC (NH₂)₂M¹X₃. In the formula, R¹ is an alkyl group, preferably an alkyl group having 1 to 5 carbon atoms, and particularly preferably a methyl group. M1 is a divalent metal ion, preferably Pb or Sn. X is a halogen, and examples thereof include F, Cl, Br, and I. All of the three Xs may be the same halogen element, or a plurality of halogens may be mixed.

Preferred examples of the compound constituting the perovskite-type crystalline material include a compound represented by the formula CH₃NH₃Pb (I₁₋ₓBrₓ)₃ (where 0≤x≤1). The spectral sensitivity characteristics of the perovskite material can be changed by changing the type and ratio of halogen. The perovskite thin film can be formed by various drying processes or solution film formation such as spin coating.

One of the charge transport layers 22 and 23 is a hole transport layer, and the other is an electron transport layer. Examples of the material of the hole transport layer include polythiophene derivatives such as poly-3-hexylthiophene (P3HT) and poly (3,4-ethylenedioxythiophene) (PEDOT), fluorene derivatives such as 2,2′, 7,7′-tetrakis-(N,N-di-p-methoxyphenylamine)-9,9′-spirobifluorene (Spiro-OMeTAD), carbazole derivatives such as polyvinylcarbazole, triphenylamine derivatives, diphenylamine derivatives, polysilane derivatives, polyaniline derivatives, and the like.

Examples of the material of the electron transport layer include metal oxides such as titanium oxide, zinc oxide, niobium oxide, zirconium oxide, and aluminum oxide.

The electrode 24 for extracting photogenerated carriers is formed on the charge transport layer 22 side of the thin-film solar battery cell 20. The electrode 25 for extracting photogenerated carriers is formed on the charge transport layer 23 side of the thin-film solar battery cell 20.

The electrode 24 may include a transparent electrode and a metal electrode, or may include only a transparent electrode, or may include only a metal electrode. Similarly, the electrode 25 may include a transparent electrode and a metal electrode, or may include only a transparent electrode, or may include only a metal electrode. As a material of the transparent electrode, a metal oxide such as ITO, zinc oxide, or tin oxide is preferably used. As a material of the metal electrode, silver, copper, aluminum, or the like is preferably used.

### Arrangement of Solar Cell Submodules

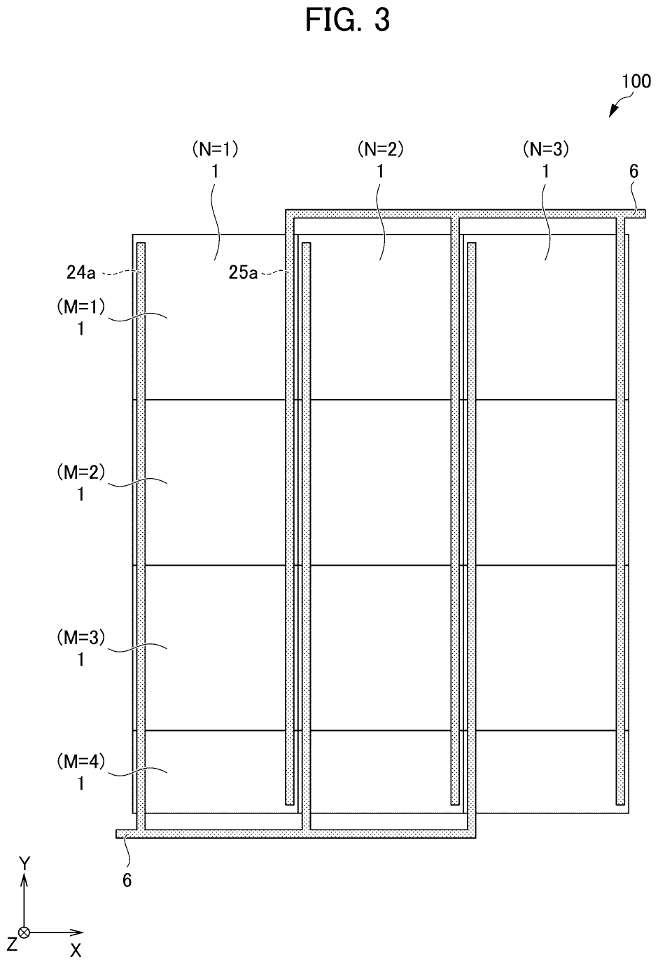

FIG. 3 is a schematic plan view of the arrangement of the solar cell submodules 1 of the solar cell module 100 shown in FIG. 1, shown from the light-receiving-surface side. In addition, FIG. 3 (and the drawings described later) are schematic views, and thus the wiring members are not limited to locations on the light-receiving side, and may include the case where the wiring members are located on the back side.

Each of the solar cell submodules 1 has a comparatively small standard size. For example, the standard size may be 300 mm×300 mm.

In the solar cell module 100, M×N number of solar cell submodules 1 are two dimensionally arranged (where M is an integer of 2 or more, and N is an integer of 1 or more). That is, the M×N number of solar cell submodules 1 are arranged in M rows in the Y direction (second direction) and in N columns in the X direction (first direction). In the example of FIG. 3, 4×3 number of solar cell submodules 1 are two dimensionally arranged.

In this way, the solar cell submodules 1 are manufactured in a relatively small standard size, and the solar cell submodules 1 of the standard size are two dimensionally arranged so as to conform to each size of the solar cell modules 100. This eliminates the need to design the solar cell submodules 1 of various sizes so as to conform to each size of the solar cell modules 100, making it possible to simplify the design of the solar cell module 100 in various sizes.

Metal electrodes 24a and 25a each extending in the Y direction (second direction) are disposed at both end portions of the solar cell submodules 1 in the X direction (integration direction: first direction). These metal electrodes 24a and 25a are connected to each other by wirings 6 extending in the Y direction (second direction) and the X direction (first direction). Thus, the columns of 1 to N columns (that is, among M×N number of solar cell submodules 1, the groups including the group of the solar cell submodules 1 in the first column to the group of the solar cell submodules 1 in the N-th column) are connected in parallel.

Further, among M×N number of solar cell submodules 1, in the group of solar cell submodules 1 in the n-th column (n is an integer of 1 or more and N or less (i.e., from 1 to N)), the solar cell submodules 1 in the first row to the M-th row (that is, the solar cell submodule 1 in the first row to the solar cell submodule 1 in the M-th row) are connected in parallel.

In the group of the solar cell submodules 1 in the n-th column, the size of the solar cell submodule 1 in the M-th row in the Y direction (second direction) is smaller than the size of the solar cell submodule in each of the other rows than the M-th row in the Y direction. For example, the solar cell submodule 1 in the M-th row is cut at any position in the Y direction (second direction) intersecting the X direction (integration direction: first direction), whereby the size is adjusted in the Y direction (second direction) intersecting the X direction (integration direction: first direction).

In the present embodiment, the metal electrodes 24a and 25a and the wiring 6 are extraction electrodes. In addition, the wiring 6 may be directly connected to the transparent electrode without providing the metal electrodes. In this case, the wiring 6 is an extraction electrode.

As described above, according to the solar cell module 100 of the present embodiment, the solar cell submodules 1 are manufactured in a relatively small standard size, and the solar cell submodules 1 of the standard size are two dimensionally arranged so as to conform to the size of the solar cell module 100. This eliminates the need to design solar cell submodules 1 of various sizes so as to conform to each size of the solar cell modules 100, making it possible to simplify the design of various sizes of the solar cell module 100.

However, even with this, only a solar cell module having a size of an integer multiple of the standard size of the thin-film solar cell sub module can be designed.

In this regard, according to the solar cell module 100 of the present embodiment, in the solar cell submodule 1 in the M-th row in the group of the solar cell submodules 1 in each of N columns, the size is adjusted in the Y direction (second direction) intersecting the X direction (integration direction: first direction), and the solar cell submodules 1 in the first row to the M-th row each including the solar cell submodule 1 in the M-th row having a different size thus adjusted are connected in parallel. In addition, since the number of integration stages in the X direction does not change, Voc of the solar cell submodule 1 in the M-th row is the same as Voc of the other solar cell submodules 1, and the solar cell submodules 1 in the first to M-th rows can be connected in parallel.

This allows the solar cell module 100 to be designed to have sizes other than an integer multiple of the standard size, and thus it is possible to design the solar cell module 100 in various sizes.

Although embodiments of the present disclosure have been described above, the present disclosure is not limited to the above embodiments, and various changes and modifications thereto can be made to the embodiments.

### First Modification

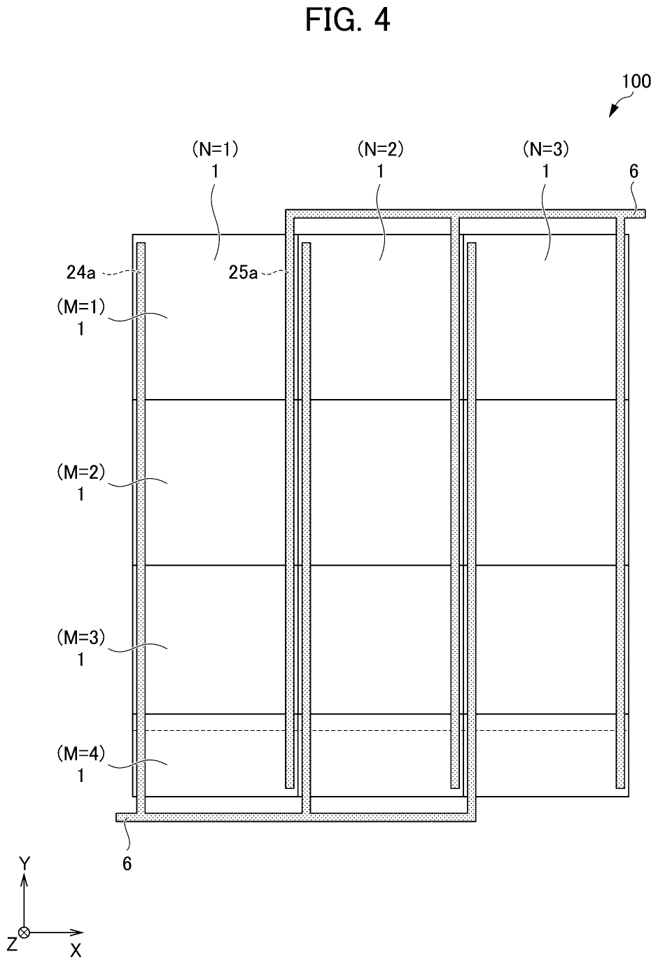

As shown in FIG. 4, among M×N number of solar cell submodules 1, in the group of the solar cell submodules 1 in the n-th column, the solar cell submodule 1 in the M-th row may overlap the adjacent solar cell submodule 1. This allows the solar cell module 100 to be designed to have sizes other than an integer multiple of the standard, and thus it is possible to design the solar cell module 100 in various sizes.

### Second Modification

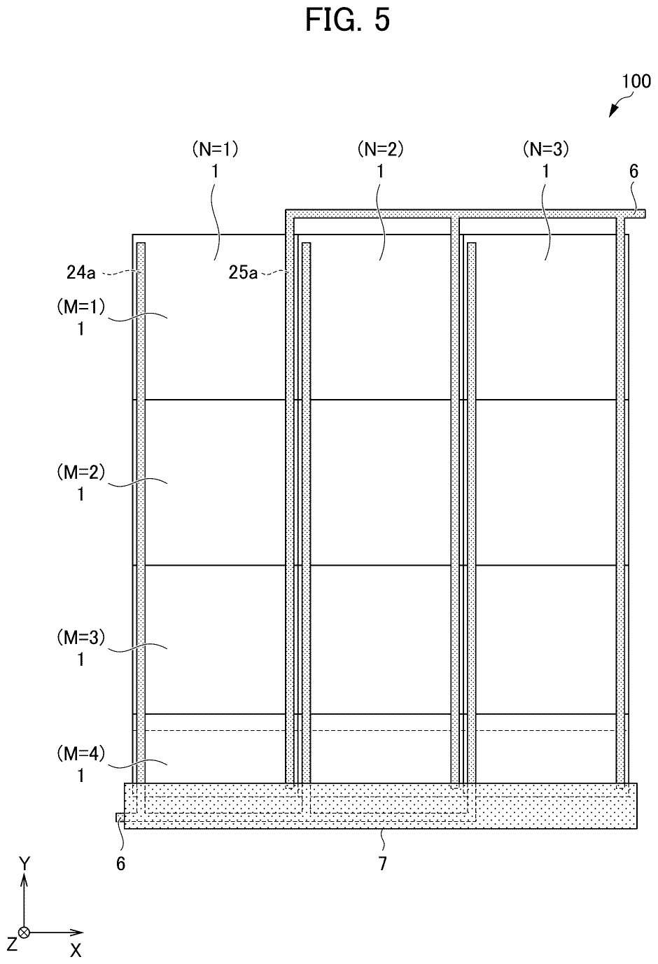

As shown in FIG. 5, among M×N number of solar cell submodules 1, the group of the solar cell submodules 1 in the n-th column may further include a light shielding member 7 that extends in the X direction (integration direction: first direction) and covers the light-receiving-surface side at an end portion in the Y direction (second direction) of the solar cell submodule 1 in the M-th row. This allows the solar cell module 100 to be designed to have sizes other than an integral multiple of the standard size, and thus it is possible to design the solar cell module 100 in various sizes.

Examples of the light shielding member 7 include a black ceramic printed film or a UV blocking coating film formed on the light-receiving-side protective member 3 such as glass, a UV absorbing material provided in the sealing material 5, a light shielding sheet disposed between the light-receiving-side protective member 3 and the sealing material 5 or between the sealing material 5 and the solar cell submodules 1, a light reflecting layer formed on the solar cell submodules 1, a frame of the cell module 100, or the like.

### Third Modification

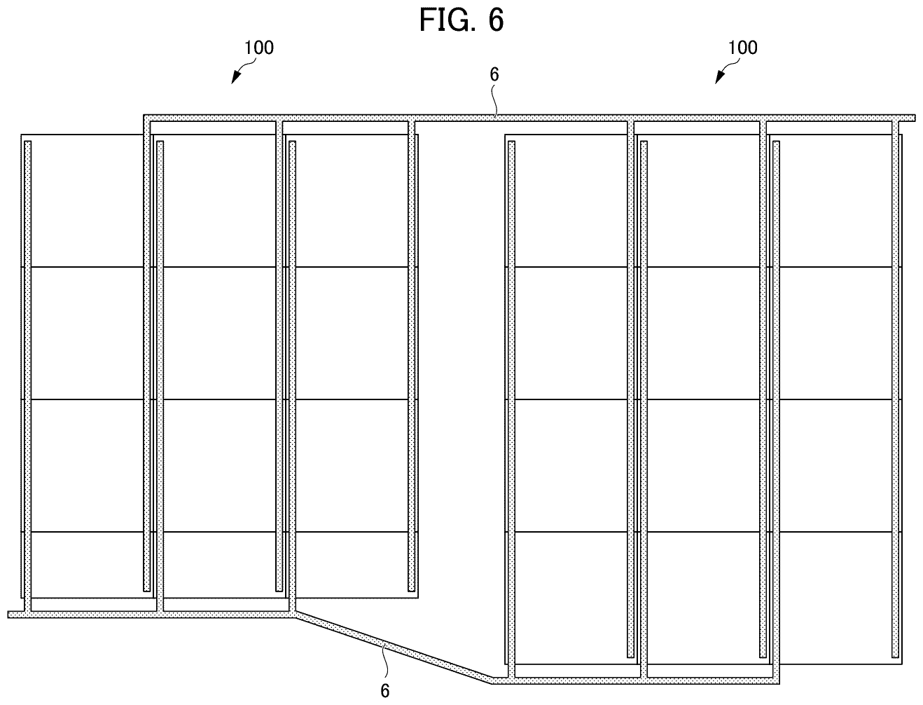

As shown in FIG. 6, depending on the shape of the installation location of the solar cell module 100. the solar cell modules 100 of different sizes may be connected in parallel. In other words, in the group of the solar cell submodules 1 in the n-th column among M×N number of solar cell submodules 1. the solar cell modules 100 in which the solar cell submodules 1 in the M-th row have different sizes may be connected in parallel to each other.

What is claimed is:

1. A solar cell module comprising:
M×N number of solar cell submodules arranged in a two dimensional manner of M rows and N columns, wherein
M is an integer of 2 or more and N is an integer of 1 or more, and
each of the M×N number of solar cell submodules comprises:
a plurality of thin-film solar battery cells that are divided in a first direction and extend in a second direction intersecting the first direction on one base material, and are integrated by connecting in series, and
an extraction electrode at an end portion in the first direction and extending in the second direction, wherein
among the M×N number of solar cell submodules, in a group of solar cell submodules in an n-th column, n is an integer from 1 to N,
the solar cell submodules of a first row to an M-th row are connected in parallel, and
a size of the solar cell submodule in the M-th row in the second direction is smaller than a size of the solar cell submodule in each row other than the M-th row in the second direction.

2. The solar cell module according to claim 1, wherein
among the M×N number of solar cell submodules, in the group of solar cell submodules in the n-th column, the solar cell submodule in the M-th row overlaps with an adjacent solar cell submodule.

3. The solar cell module according to claim 1, further comprising:
a light shield that extends in the first direction and covers a light-receiving-surface side at an end portion in the second direction of the solar cell submodule in the M-th row, among the M×N number of solar cell submodules, in the group of solar cell submodules in the n-th column.
